(19) United States
(12) Patent Application Publication
(10) Pub. No.: US 2025/0260389 A1
(43) Pub. Date: Aug. 14, 2025

(54) ELECTRONIC COMPONENT

(71) Applicant: TDK Corporation, Tokyo (JP)

(72) Inventor: Takuya SATO, Tokyo (JP)

(73) Assignee: TDK Corporation, Tokyo (JP)

(21) Appl. No.: 19/052,313

(22) Filed: Feb. 13, 2025

(30) Foreign Application Priority Data
Feb. 14, 2024 (JP) 2024-020063

(51) Int. Cl. H03H 9/64

(52) U.S. Cl. CPC H03H 9/6483

(57) ABSTRACT

An electronic component includes a first main body including a first element, a second main body including a second element, and a circuit including the first element and the second element. The first main body further includes a first columnar conductor connected to the ground. The first element is a capacitor including a capacitor conductor layer. The capacitor conductor layer is arranged between the second element and the first columnar conductor.

### CROSS-REFERENCE TO RELATED APPLICATION

This application claims the benefit of Japanese Priority Patent Application No. 2024-020063 filed on Feb. 14, 2024, the entire contents of which are incorporated herein by reference.

### BACKGROUND

The disclosure relates to an electronic component including a main body and a mounted component that is mounted to the main body.

A filter such as a low-pass filter, a high-pass filter, and a band-pass filter is formed by using a plurality of resonators. As examples of the resonators used in such a filter, there have been known an LC resonator formed by using an inductor and a capacitor and an acoustic wave resonator formed by using an acoustic wave element. The acoustic wave element is an element that utilizes an acoustic wave. Examples of the acoustic wave element include a surface acoustic wave element that utilizes a surface acoustic wave and a bulk acoustic wave element that utilizes a bulk acoustic wave.

WO 2007/119356 A discloses a multilayer band-pass filter including a plurality of LC parallel resonators, wherein adjacent LC parallel resonators are coupled to each other. The LC parallel resonator is formed by a capacitor electrode and an inductor electrode. In the inductor electrode, a via electrode passing through in a stacking direction of dielectric layers and a line path electrode extending in a vertical direction with respect to the stacking direction of the dielectric layers form a coil-like shape.

WO 2013/061694 A discloses an acoustic wave filter formed of a surface acoustic wave filter with a ladder-type circuit configuration and an acoustic wave filter formed of a longitudinally-coupled surface acoustic wave resonator filter.

As a filter device, a hybrid-type filter device formed by using an LC resonator and an acoustic wave resonator is also known, in addition to a filter device formed by using only an LC resonator or only an acoustic wave resonator. In the hybrid-type filter device, for example, a second main body including an acoustic wave resonator is mounted on a first main body including an LC resonator.

In general, the overall characteristics of the filter device are adjusted by adjusting the characteristics of each of the plurality of elements of the filter device. In the hybrid-type filter device, the characteristics of each of the LC resonator and the acoustic wave resonator are adjusted. However, depending on a product, it may be difficult to achieve overall adjustment only with the characteristics of the acoustic wave resonator, or adjusting the characteristics of the elastic wave resonator itself may be difficult.

The issue described above is not limited to a case in which the second main body includes the acoustic wave resonator, and also applies in a situation where it is difficult to achieve overall adjustment only with the characteristics of the elements included in the second main body or adjusting the characteristics of the elements included in the second main body itself is difficult.

### SUMMARY

An electronic component according to one embodiment of a first aspect of the disclosure includes a first main body including a plurality of dielectric layers being stacked and a first element, a second main body being mounted to the first main body and including a second element, and a circuit including the first element and the second element. The first main body further includes a first columnar conductor extending in a direction parallel to a stacking direction of the plurality of dielectric layers and being connected to the ground. The first element is a capacitor including a capacitor conductor layer extending along an orthogonal direction orthogonal to the stacking direction. The capacitor conductor layer is arranged between the second element and the first columnar conductor.

An electronic component according to one embodiment of a second aspect of the disclosure includes a first main body including a plurality of dielectric layers, a capacitor, and an inductor, a second main body being mounted to the first main body and including an acoustic wave element, and a circuit. The circuit includes a first signal port, a second signal port, and a signal path connecting the first signal port and the second signal port to each other. In a circuit configuration, the acoustic wave element is provided between the signal path and the ground. The capacitor and the inductor are connected to each other in series, and are provided between the acoustic wave element and the ground in the circuit configuration.

Other and further objects, features and advantages of the technology will appear more fully from the following description.

### BRIEF DESCRIPTION OF THE DRAWINGS

The accompanying drawings are included to provide a further understanding of the disclosure and are incorporated in and constitute a part of this specification. The drawings illustrate example embodiments and, together with the specification, serve to explain the principles of the technology.

FIG. 1 is a perspective view showing an electronic component according to an exemplary embodiment of the disclosure.

FIG. 2 is a perspective view showing a first main body in the exemplary embodiment of the disclosure.

FIG. 3 is a perspective view showing the first main body in the exemplary embodiment of the disclosure.

FIG. 4 is a block diagram schematically showing a circuit configuration of a band-pass filter circuit in the exemplary embodiment of the disclosure.

FIG. 5 is a circuit diagram showing an example of a configuration of a third circuit section in the exemplary embodiment of the disclosure.

FIG. 6 is a perspective view showing a part of the internal structure of the first main body in the exemplary embodiment of the disclosure.

FIG. 7 is a plan view showing a part of the internal structure of the first main body in the exemplary embodiment of the disclosure.

FIG. 8 is a side view showing a part of the internal structure of the first main body in the exemplary embodiment of the disclosure.

FIG. 9 is a characteristic chart showing pass attenuation characteristics of a sub circuit, which are obtained by a first simulation.

FIG. 10 is a characteristic chart showing pass attenuation characteristics of the sub circuit, which are obtained by a second simulation.

FIG. 11 is a characteristic chart showing return attenuation characteristics of the sub circuit, which are obtained by the second simulation.

FIG. 12 is a side view showing a part of the internal structure of a first main body in a first modification example of the electronic component according to the exemplary embodiment of the disclosure.

FIG. 13 is a side view showing a part of the internal structure of a first main body in a second modification example of the electronic component according to the exemplary embodiment of the disclosure.

### DETAILED DESCRIPTION

An object of the disclosure is to provide an electronic component including a first main body and a second main body mounted to the first main body, wherein elements in the first main body enable the overall characteristics of the electronic component to achieve the desired characteristics.

In the following, some example embodiments and modification examples of the disclosure are described in detail with reference to the accompanying drawings. Note that the following description is directed to illustrative examples of the disclosure and not to be construed as limiting the technology. Factors including, without limitation, numerical values, shapes, materials, components, positions of the components, and how the components are coupled to each other are illustrative only and not to be construed as limiting the technology. Further, elements in the following example embodiments which are not recited in a most-generic independent claim of the disclosure are optional and may be provided on an as-needed basis. The drawings are schematic and are not intended to be drawn to scale. Like elements are denoted with the same reference numerals to avoid redundant descriptions.

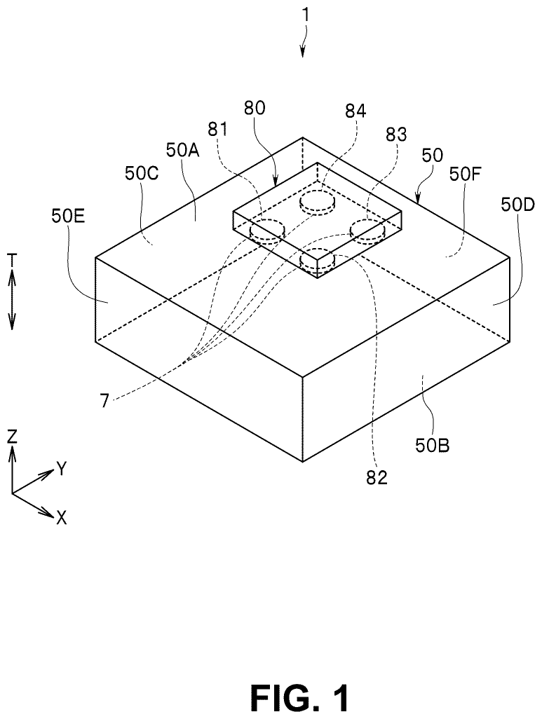

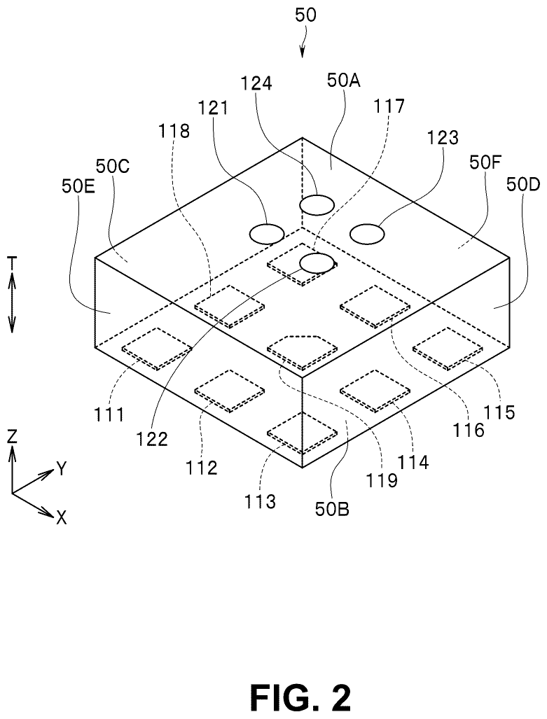

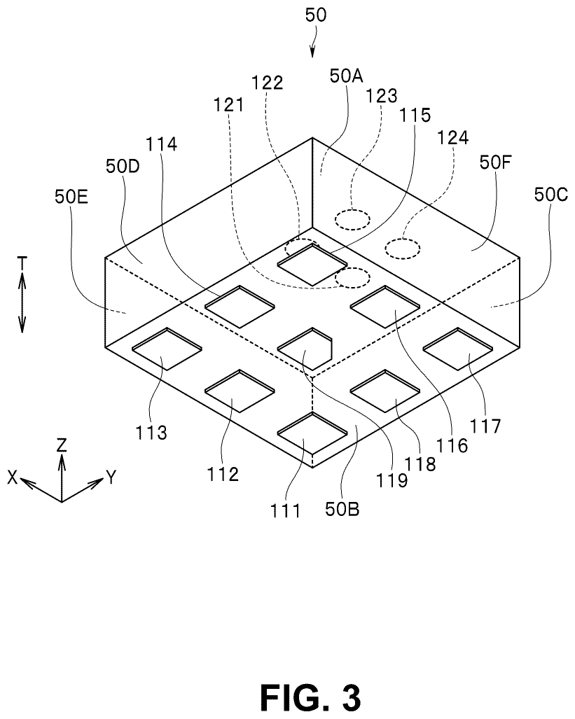

First, with reference to FIG. 1 to FIG. 3, a configuration of an electronic component 1 according to the exemplary embodiment of the disclosure is described. FIG. 1 is a perspective view showing the electronic component 1. FIG. 2 and FIG. 3 are perspective views showing a first main body.

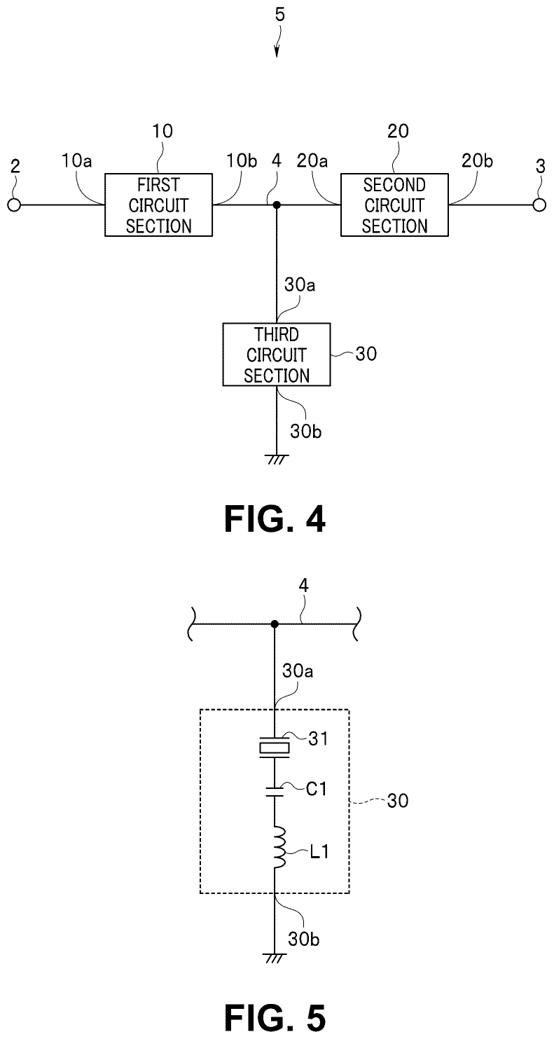

The electronic component 1 according to the exemplary embodiment includes a first main body 50 and a second main body 80 mounted to the first main body 50. The electronic component 1 further includes a circuit including a plurality of elements provided in the first main body 50 and at least one element provided in the second main body 80. In the exemplary embodiment, the electronic component 1 includes, as the circuit described above, a band-pass filter circuit 5 that selectively passes a signal of a frequency within a predetermined passband. Note that the band-pass filter circuit 5 is shown in FIG. 4 described below.

The first main body 50 includes a plurality of dielectric layers being stacked together and a plurality of conductors (a plurality of conductor layers and a plurality of through holes). Each of the plurality of dielectric layers is formed of a dielectric material. In the exemplary embodiment, for example, low-temperature co-fired ceramics (LTCC) are used as the dielectric material. The specific dielectric constant of the dielectric material may be, for example, 8 or greater, and is preferably 10 or greater.

The first main body 50 includes a first surface 50A and a second surface 50B located at both ends in a stacking direction T of the plurality of dielectric layers, and four side surfaces 50C to 50F connecting the first surface 50A and the second surface 50B to each other. The side surfaces 50C and 50D are opposite to each other, and the side surfaces 50E and 50F are also opposite to each other. The side surfaces 50C to 50F are perpendicular to the first surface 50A and the second surface 50B.

Here, as shown in FIG. 1 to FIG. 3, an X direction, a Y direction, and a Z direction are defined. The X direction, the Y direction, and the Z direction are orthogonal to one another. In the exemplary embodiment, a direction parallel to the stacking direction T is defined as the Z direction. The Z direction is also a direction parallel to a direction in which the first main body 50 and the second main body 80 are arrayed. A direction opposite to the X direction is defined as a −X direction, a direction opposite to the Y direction is defined as a −Y direction, and a direction opposite to the Z direction is defined as a −Z direction. The expression “when seen in the(a) predetermined direction (for example, the stacking direction T)” indicates that a target object is seen from a position away from the target object in the predetermined direction or a direction parallel to the predetermined direction.

As shown in FIG. 1 to FIG. 3, the first surface 50A is located at the end of the first main body 50 in the Z direction. The first surface 50A is a top surface of the first main body 50, and is a mounting surface for mounting the second main body 80. The second surface 50B is located at the end of the first main body 50 in the −Z direction. The second surface 50B is a bottom surface of the first main body 50. FIG. 2 shows the first main body 50 when seen from the first surface 50A side. FIG. 3 shows the first main body 50 when seen from the second surface 50B side.

The side surface 50C is located at the end of the first main body 50 in the −X direction. The side surface 50D is located at the end of the first main body 50 in the X direction. The side surface 50E is located at the end of the first main body 50 in the −Y direction. The side surface 50F is located at the end of the first main body 50 in the Y direction.

The first main body 50 further includes a plurality of electrodes 111, 112, 113, 114, 115, 116, 117, 118, and 119 that are provided to the second surface 50B of the first main body 50. The electrodes 111, 112, and 113 are arrayed in the X direction in the stated order at positions closer to the side surface 50E than the side surface 50F. The electrodes 115, 116, and 117 are arrayed in the −X direction in the stated order at positions closer to the side surface 50F than the side surface 50E.

The electrode 114 is arranged between the electrode 113 and the electrode 115. The electrode 118 is arranged between the electrode 111 and the electrode 117. The electrode 119 is arranged between the electrode 112 and the electrode 116. The electrode 119 is arranged substantially at the center of the second surface 50B.

The first main body 50 further includes four electrodes 121, 122, 123, and 124 provided to the first surface 50A of the first main body 50. The electrodes 121 and 122 are arrayed in the X direction in the stated order at positions closer to the side surface 50E than the side surface 50F. The electrodes 123 and 124 are arrayed in the −X direction in the stated order at positions ahead of the electrodes 121 and 122 in the Y direction.

The second main body 80 further includes four electrodes 81, 82, 83, and 84. When the second main body 80 is mounted to the first main body 50, the electrodes 81 to 84 face the electrodes 121 to 124 of the first main body 50, respectively. For example, the electrodes 81 to 84 are physically connected to the electrodes 121 to 124 via solder bumps 7.

The planar shape of the first main body 50 (the shape when seen in the stacking direction T) is different from the planar shape of the second main body 80 in size. In the example shown in FIG. 1, the planar shape of the first main body 50 is larger than the planar shape of the second main body 80.

In the example shown in FIG. 1, the second main body 80 is arranged so as to overlap with the gravity center of the first surface 50A when seen in the stacking direction T. The gravity center of the second main body 80 when seen in the stacking direction T may match or may not match with the gravity center of the first surface 50A.

The electronic component 1 may further include a sealing portion (omitted in illustration) that seals the second main body 80. The sealing portion (omitted in illustration) covers the periphery of the second main body 80 and at least a part of the first surface 50A of the first main body 50. The sealing portion may further cover the side surfaces 50C to 50F of the first main body 50. The sealing portion is formed of, for example, a resin.

Next, with reference to FIG. 4, the circuit configuration of the band-pass filter circuit 5 of the electronic component 1 is described. FIG. 4 is a block diagram schematically showing the circuit configuration of the band-pass filter circuit 5. The band-pass filter circuit 5 includes a first signal port 2, a second signal port 3, and a signal path 4 connecting the first signal port 2 and the second signal port 3 to each other.

Each of the first and second signal ports 2 and 3 is a port for inputting or outputting a signal. In other words, when a signal is input to the first signal port 2, a signal is output from the second signal port 3. When a signal is input to the second signal port 3, a signal is output from the first signal port 2.

The two electrodes of the electrodes 111 to 119 shown in FIG. 2 and FIG. 3 correspond to the first and second signal ports 2 and 3. Among the electrodes 111 to 119, the seven electrodes other than the two electrodes described above may be connected to the ground.

The band-pass filter circuit 5 further includes a first circuit section 10, a second circuit section 20, and a third circuit section 30. The first circuit section 10 and the second circuit section 20 are provided in the signal path 4. In the circuit configuration, the third circuit section 30 is provided between the signal path 4 and the ground. Note that, in the present application, the expression “in the(a) circuit configuration” is used to indicate not a layout in a physical configuration but a layout in a circuit diagram.

The first circuit section 10 includes a first end 10a and a second end 10b. The second circuit section 20 includes a first end 20a and a second end 20b. The third circuit section 30 includes a first end 30a and a second end 30b. The first end 10a of the first circuit section 10 is connected to the first signal port 2. The first end 20a of the second circuit section 20 is connected to the second end 10b of the first circuit section 10. The second end 20b of the second circuit section 20 is connected to the second signal port 3.

The first end 30a of the third circuit section 30 is connected to the signal path 4 between the second end 10b of the first circuit section 10 and the first end 20a of the second circuit section 20. The second end 30b of the third circuit section 30 is connected to the ground.

The band-pass filter circuit 5 includes the first to third circuit sections 10, 20, and 30. For example, the band-pass filter circuit 5 can be formed by connecting a high-pass filter circuit and a low-pass filter circuit to each other in series. One of the first circuit section 10 and the second circuit section 20 may be a high-pass filter circuit. The other of the first circuit section 10 and the second circuit section 20 may be a low-pass filter circuit. Alternatively, at least one of the first circuit section 10 and the second circuit section 20 may be a circuit including a high-pass filter circuit and a low-pass filter circuit.

The first circuit section 10 and the second circuit section 20 include a plurality of elements provided in the first main body 50. The plurality of elements include a plurality of inductors and a plurality of capacitors. The plurality of inductors are formed by a plurality of conductors in the first main body 50. The plurality of capacitors is formed of the plurality of conductors and a plurality of dielectrics in the first main body 50. Each of the plurality of dielectrics is a part of the plurality of dielectric layers forming the first main body 50.

At least one of the first circuit section 10 and the second circuit section 20 may further include at least one element provided in the second main body 80.

The third circuit section 30 includes a first element provided in the first main body 50 and a second element provided in the second main body 80. The first element and the second element are connected to each other via some of the plurality of electrodes 81 to 84 shown in FIG. 1 and some of the plurality of electrodes 121 to 124 shown in FIG. 2 and FIG. 3.

In the exemplary embodiment, in particular, the first element is a capacitor, and the second element is an acoustic wave element. The capacitor includes a plurality of capacitor conductor layers in the first main body 50 and a dielectric. Each of the plurality of capacitor conductor layers extends along an orthogonal direction orthogonal to the stacking direction T. The dielectric interposed between the plurality of capacitor conductor layers is a part of the plurality of dielectric layers forming the first main body 50. Hereinafter, the dielectric of the capacitor (the first element) is referred to as a first dielectric. As the first dielectric, various ceramic materials, various glass ceramic materials used in low-temperature co-fired ceramics (LTCC), or a mixture thereof can be used.

The acoustic wave element includes a dielectric. Hereinafter, the dielectric of the acoustic wave element (the second element) is referred to as the second dielectric. The acoustic wave element may be a bulk acoustic wave element or a surface acoustic wave element. In the bulk acoustic wave element, vibration of the second dielectric is used. In the surface acoustic wave element, the second dielectric is utilized as a substrate. A dielectric that is generally used as an acoustic wave element can be used as the second dielectric.

FIG. 5 shows an example of a configuration of the third circuit section 30. In FIG. 5, a reference symbol C1 represents the capacitor being the first element, and a reference symbol 31 represents the acoustic wave element being the second element. The third circuit section 30 further includes an inductor L1. The inductor L1 is provided in the first main body 50.

The capacitor C1 and the acoustic wave element 31 are connected to each other in series, and are provided between the signal path 4 and the ground in the circuit configuration. The capacitor C1 and the inductor L1 are connected to each other in series, and are provided between the acoustic wave element 31 and the ground in the circuit configuration. In the example shown in FIG. 5, one end of the acoustic wave element 31 is connected to the first end 30a of the third circuit section 30. One end of the capacitor C1 is connected to the other end of the acoustic wave element 31. One end of the inductor L1 is connected to the other end of the capacitor C1. The other end of the inductor L1 is connected to the second end 30b of the third circuit section 30.

The inductor L1 may include a plurality of inductor portions. In the circuit configuration, the plurality of inductor portions may be connected to each other in parallel. The plurality of inductor portions are described below.

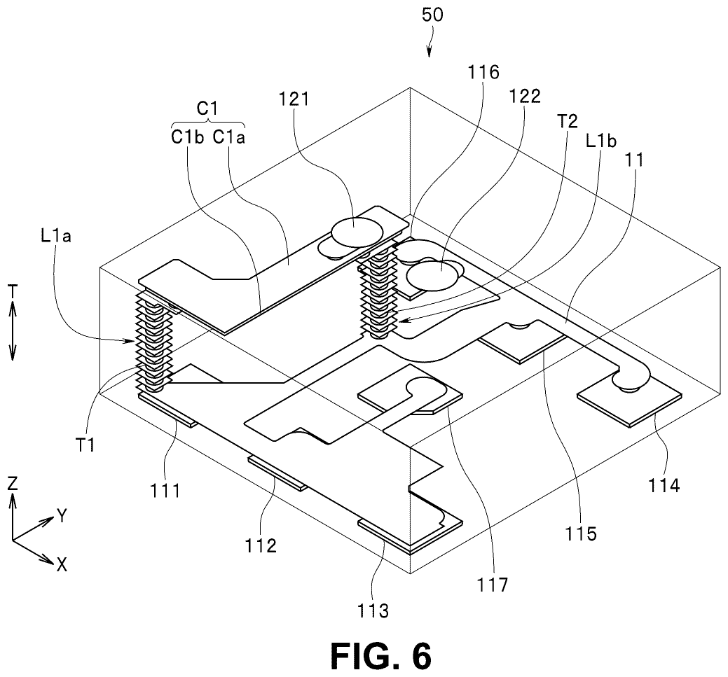

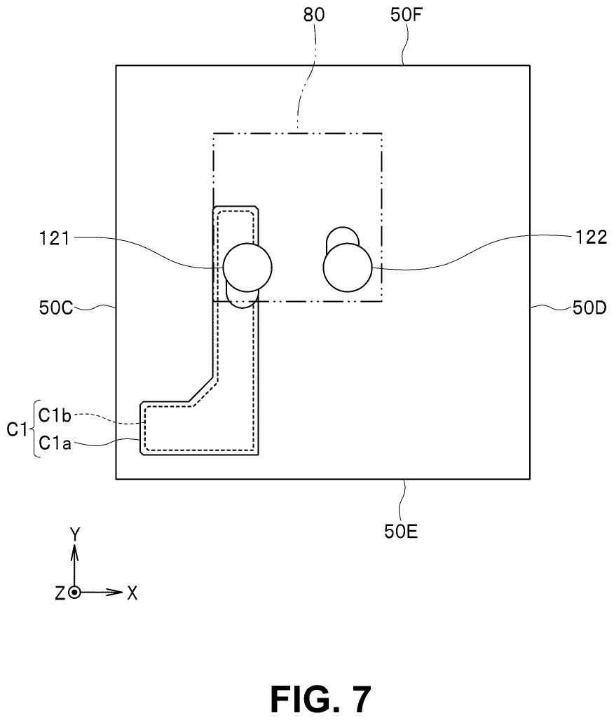

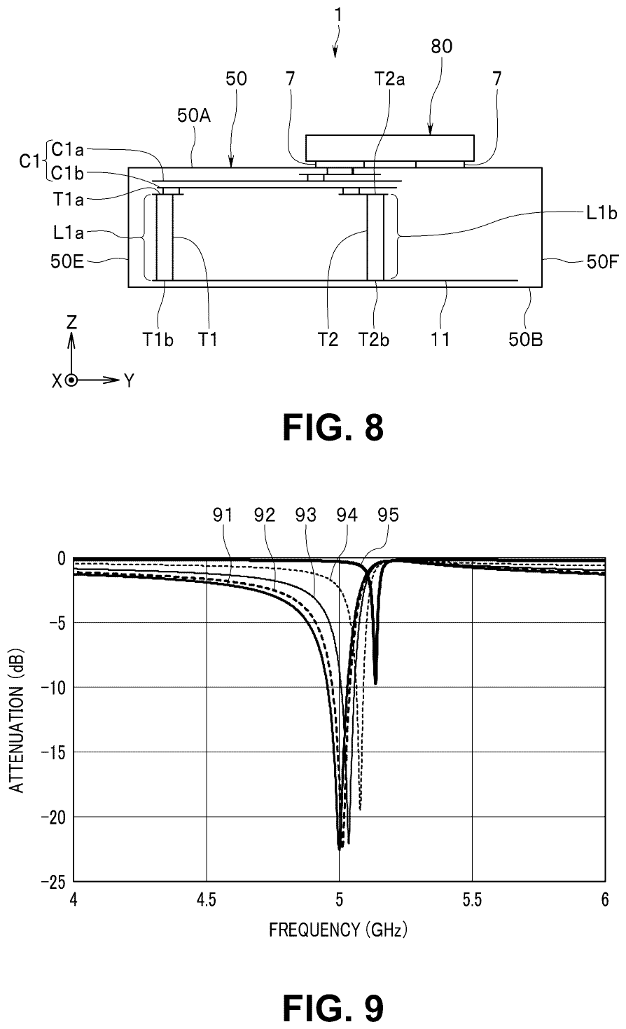

Next, with reference to FIG. 6 to FIG. 8, the structural features of the electronic component 1 according to the exemplary embodiment are described. FIG. 6 is a perspective view showing a part of the internal structure of the first main body 50. FIG. 7 is a plan view showing a part of the internal structure of the first main body 50. FIG. 8 is a side view showing a part of the internal structure of the first main body 50.

First, the structure of the capacitor C1 is described. The capacitor C1 is formed of capacitor conductor layers C1a and C1b that are arranged at a predetermined interval in the stacking direction T and face each other and a dielectric between the capacitor conductor layer C1a and the capacitor conductor layer C1b. Each of the capacitor conductor layers C1a and C1b extends along an orthogonal direction orthogonal to the stacking direction T.

As shown in FIG. 8, the capacitor conductor layers C1a and C1b are arrayed along the Z direction in the stated order. The capacitor conductor layer C1a is arranged between the capacitor conductor layer C1b and the first surface 50A. As shown in FIG. 7, the capacitor conductor layer C1a overlaps with the capacitor conductor layer C1b when seen in the Z direction. In the exemplary embodiment, in particular, the planar shape of the capacitor conductor layer C1a (the shape when seen in the Z direction) and the planar shape of the capacitor conductor layer C1b are similar to each other. In the example shown in FIG. 7, the planar shape of the capacitor conductor layer C1a and the planar shape of the capacitor conductor layer C1b are both L-shapes. The planar shape of the capacitor conductor layer C1a is larger than the planar shape of the capacitor conductor layer C1b. The capacitor conductor layer C1a overlaps with the entire capacitor conductor layer C1b when seen in the Z direction.

The capacitor conductor layer C1a is electrically connected to the electrode 121 via a conductor such as a through hole. Although omitted in illustration, the acoustic wave element 31 is electrically connected to the electrode 81. Thus, the capacitor C1 is connected to the acoustic wave element 31 in series via the electrodes 81 and 121.

Next, the structure of the inductor L1 is described. The inductor L1 includes a first inductor portion L1a and a second inductor portion L1b that are connected to each other in parallel. Here, a columnar structure formed with a plurality of through holes being connected in series is referred to as a columnar conductor. The columnar conductor extends in a direction parallel to the stacking direction T. The first main body 50 includes a first columnar conductor T1 and a second columnar conductor T2. The first inductor portion L1a is formed of the first columnar conductor T1. The second inductor portion L1b is formed of the second columnar conductor T2.

As shown in FIG. 8, the first columnar conductor T1 is arranged between the capacitor conductor layer C1a and the second surface 50B of the first main body 50. The first columnar conductor T1 includes a first end T1a and a second end T1b that are located on sides opposite to each other in a direction parallel to the stacking direction T. The first end T1a of the first columnar conductor T1 is electrically connected to the capacitor conductor layer C1b via a conductor such as a through hole.

As shown in FIG. 8, the second columnar conductor T2 is arranged between the capacitor conductor layer C1a and the second surface 50B of the first main body 50. The second columnar conductor T2 includes a first end T2a and a second end T2b that are located on sides opposite to each other in a direction parallel to the stacking direction T. The first end T2a of the second columnar conductor T2 is electrically connected to the capacitor conductor layer C1b via a conductor such as a through hole.

As described above, the first end T1a of the first columnar conductor T1 and the first end T2a of the second columnar conductor T2 are connected to the capacitor conductor layer C1b via a conductor such as a through hole. The capacitor conductor layer C1b functions as both a “capacitor conductor layer” and a “first conductor layer” in the disclosure.

The first main body 50 further includes a conductor layer 11 extending along an orthogonal direction orthogonal to the stacking direction T. The second end T1b of the first columnar conductor T1 and the second end T2b of the second columnar conductor T2 are electrically connected to the conductor layer 11. The conductor layer 11 is connected to the ground via a conductor such as a through hole and some of the electrodes 111 to 119. The first columnar conductor T1 and the second columnar conductor T2 are connected to each other in parallel via the capacitor conductor layer C1b, the conductor layer 11, and a conductor such as a through hole. The first columnar conductor T1 and the second columnar conductor T2 is connected to the ground via the conductor layer 11, a conductor such as a through hole, and some of the electrodes 111 to 119. The conductor layer 11 corresponds to a “second conductor layer” in the disclosure.

Note that the first end T1a of the first columnar conductor T1 may be connected directly to the capacitor conductor layer C1b without a conductor such as a through hole. Similarly, the first end T2a of the second columnar conductor T2 may be connected directly to the capacitor conductor layer C1b without a conductor such as a through hole.

Next, the features related to arrangement of the capacitor C1 and the acoustic wave element 31 are described. In FIG. 7, a rectangular region that is surrounded by a two-dot chain line and is denoted with a reference symbol 80 indicates a region of the first surface 50A of the first main body 50 to which the second main body 80 is mounted. The second main body 80 overlaps with a part of the capacitor C1 when seen in the stacking direction T. Although omitted in illustration, the acoustic wave element 31 is arranged ahead of the capacitor C1 in the Z direction. No element is arranged between the capacitor C1 and the acoustic wave element 31.

The capacitor conductor layers C1a and C1b forming the capacitor C1 are arranged between the acoustic wave element 31 and the first and second columnar conductors T1 and T2 forming the first and second inductor portions L1a and L1b. The capacitor conductor layers C1a and C1b entirely cover the first and second columnar conductors T1 and T2 when seen in the Z direction.

Next, actions and effects of the electronic component 1 according to the exemplary embodiment are described. In the exemplary embodiment, the capacitor conductor layers C1a and C1b are arranged between the acoustic wave element 31 and the first and second columnar conductors T1 and T2. With this, according to the exemplary embodiment, magnetic coupling between the acoustic wave element 31 and the first and second columnar conductors T1 and T2 can be suppressed. As a result, according to the exemplary embodiment, it is possible to suppress deviation of the overall characteristics of the electronic component 1 from the desired characteristics due to magnetic coupling between the acoustic wave element 31 and the first and second columnar conductors T1 and T2. In other words, according to the exemplary embodiment, the capacitor conductor layers C1a and C1b enable the overall characteristics of the electronic component 1 to achieve the desired characteristics.

In the exemplary embodiment, both the first end T1a of the first columnar conductor T1 and the first end T2a of the second columnar conductor T2 are connected to the capacitor conductor layer C1b, and both the second end T1b of the first columnar conductor T1 and the second end T2b of the second columnar conductor T2 are connected to the conductor layer 11. Thus, in the exemplary embodiment, a direction in which an electric current flows in the first columnar conductor T1 and a direction in which an electric current flows in the second columnar conductor T2 match with each other, and a magnetic field generated in the periphery of the first columnar conductor T1 and a magnetic field generated in the periphery of the second columnar conductor T2 cancel each other. With this, according to the exemplary embodiment, it is also possible to suppress deviation of the overall characteristics of the electronic component 1 from the desired characteristics due to magnetic coupling between the acoustic wave element 31 and the first and second columnar conductors T1 and T2. In other words, according to the exemplary embodiment, the capacitor conductor layer C1b, the first and second columnar conductors T1 and T2, and the conductor layer 11 enable the overall characteristics of the electronic component 1 to achieve the desired characteristics.

In the exemplary embodiment, in the circuit configuration, the acoustic wave element 31 is provided between the signal path 4 and the ground. The capacitor C1 and the inductor L1 are connected to each other in series, and are provided between the acoustic wave element 31 and the ground in the circuit configuration. The capacitor C1 includes a function of increasing a resonance frequency of a sub circuit including the third circuit section 30. The function is described below with reference to a result of a first simulation.

In the first simulation, a model of the sub circuit including the third circuit section 30 is used. The model of the sub circuit includes a first signal port, a second signal port, a signal path connecting the first signal port and the second signal port to each other, and the third circuit section 30 provided between the signal path and the ground. In the model of the sub circuit, the third circuit section 30 includes an acoustic wave element provided between the signal path and the ground and a capacitor provided between the signal path and the acoustic wave element.

In the first simulation, the model of the sub circuit described above is used to obtain the pass attenuation characteristics of the sub circuit while changing the capacitance of the capacitor within a range from 0.3 to ∞ pF. The pass attenuation characteristics in a case in which the capacitance of the capacitor is ∞ pF indicates the pass attenuation characteristics in a case in which the capacitor is not provided. In the first simulation, each of a Q value of a resonance frequency and a Q value of an anti-resonant frequency of the acoustic wave element is set to 300, and an electromechanical coupling coefficient of the acoustic wave element is set to 0.091.

FIG. 9 is a characteristic chart showing the pass attenuation characteristics of the sub circuit, which are obtained by the first simulation. In FIG. 9, the horizontal axis represents frequency, and the vertical axis represents attenuation. In FIG. 9, a reference symbol 91 represents the pass attenuation characteristics in a case in which the capacitance of the capacitor is ∞ pF, a reference symbol 92 represents the pass attenuation characteristics in a case in which the capacitance of the capacitor is 10 pF, a reference symbol 93 represents the pass attenuation characteristics in a case in which the capacitance of the capacitor is 3 pF, a reference symbol 94 represents the pass attenuation characteristics in a case in which the capacitance of the capacitor is 1 pF, and a reference symbol 95 represents the pass attenuation characteristics in a case in which the capacitance of the capacitor is 0.3 pF.

As shown in FIG. 9, the resonance frequency of the sub circuit is increased as the capacitance of the capacitor is reduced. According to the exemplary embodiment, the resonance frequency of the sub circuit including the third circuit section 30 can be adjusted by the capacitor. In particular, a resonance frequency of the sub circuit in a case in which the capacitor is provided is higher than a resonance frequency of the sub circuit in a case in which the capacitance of the capacitor is ∞ pF, in other words, the capacitor is not provided.

Note that the characteristics of the sub circuit can also be adjusted by the acoustic wave element. Description is made below on a second simulation where the characteristics of the sub circuit are examined when the characteristics of the acoustic wave element are changed. In the second simulation, the model of the sub circuit is used to obtain the pass attenuation characteristics and the return attenuation characteristics of the sub circuit in a first case in which the capacitance of the capacitor is set to 0.3 pF, each of a Q value of a resonance frequency and a Q value of an anti-resonant frequency of the acoustic wave element is set to 500, and an electromechanical coupling coefficient of the acoustic wave element is set to 0.13. In the second simulation, the model of the sub circuit is used to obtain the pass attenuation characteristics and the return attenuation characteristics of the sub circuit in a second case in which the capacitance of the capacitor is set to 0.3 pF, each of a Q value of a resonance frequency and a Q value of an anti-resonant frequency of the acoustic wave element is set to 300, and an electromechanical coupling coefficient of the acoustic wave element is set to 0.091.

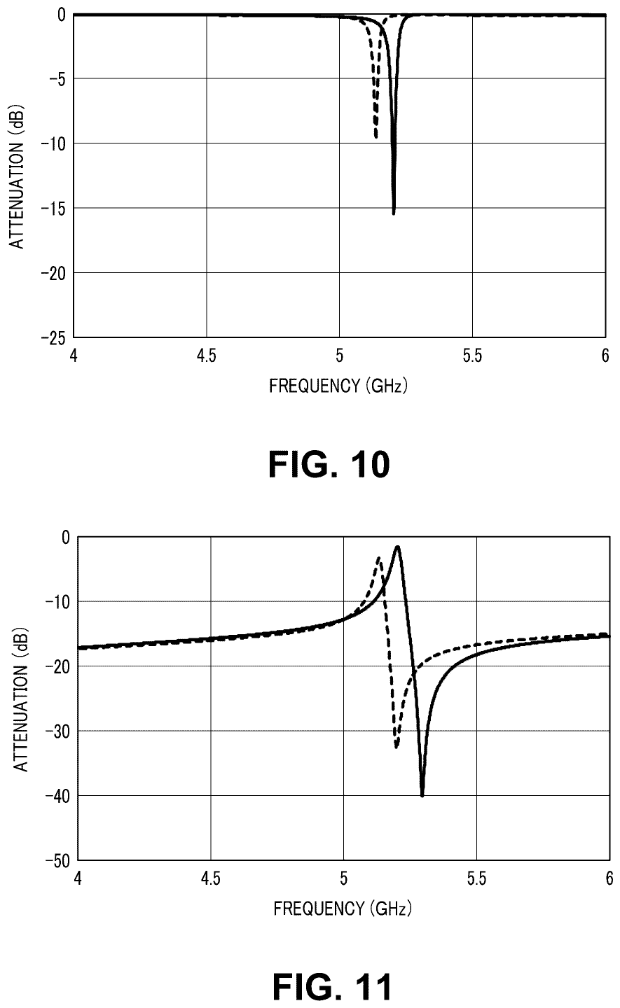

FIG. 10 is a characteristic chart showing the pass attenuation characteristics of the sub circuit, which are obtained by the second simulation. FIG. 11 is a characteristic chart showing the return attenuation characteristics of the sub circuit, which are obtained by the second simulation. In FIG. 10 and FIG. 11, the horizontal axis represents frequency, and the vertical axis represents attenuation. In FIG. 10 and FIG. 11, the solid curved line indicates the characteristics in the first case, and the broken curved line indicates the characteristics in the second case. As understood from FIG. 10 and FIG. 11, the characteristics of the sub circuit can also be adjusted by the acoustic wave element.

According to the exemplary embodiment, the characteristics of the sub circuit can be adjusted by the capacitor C1 and the acoustic wave element 31 as understood from the results of the first and second simulations.

Next, other effects of the exemplary embodiment are described. The dielectric has characteristics that change depending on a temperature. Thus, the band-pass filter circuit 5 formed by the elements including the dielectric also has characteristics that change depending on a temperature. Here, description is made while focusing on a resonance frequency of the dielectric material. As an indicator showing the temperature dependency of the resonance frequency of the dielectric material, a temperature coefficient TCF of the resonance frequency is known. The temperature coefficient TCF (a unit is ppm/K) of the resonance frequency is expressed by Equation (1) given below as defined in Japanese Industrial Standards R1627 (JIS R1627) (Testing method for dielectric properties of fine ceramics at microwave frequency). Note that fᵣₑf represents a resonance frequency at a reference temperature t_{ref}, and f_{T} represents a resonance frequency at a predetermined temperature t.

$$TCF = [ ( {f}_{T} - {f}_{ref} ) / \{ {f}_{ref} ( t - {t}_{ref} ) \} ] \times 1 {0}^{6} . \qquad ( 1 )$$

In general, the temperature dependency of the pass attenuation characteristics of the band-pass filter circuit 5 can be suppressed by using the element including the dielectric having a small absolute value for the temperature coefficient TCF of the resonance frequency. However, depending on the element, it may be difficult to use the dielectric having a small absolute value for the temperature coefficient TCF of the resonance frequency. The absolute value for the temperature coefficient TCF of the resonance frequency can be reduced by combining materials having different temperature coefficients TCF of the resonance frequency. However, when the acoustic wave element 31 is formed by using a dielectric material obtained by combining a plurality of materials, a problem is a cost increase of the acoustic wave element 31. Another problem is a difficulty in achieving a combination of such materials that can satisfy the characteristics of the acoustic wave element 31 and the characteristics of the band-pass filter circuit 5.

In the exemplary embodiment, the first dielectric used for the capacitor C1 (the first element) is formed of a first dielectric material having a first value for the temperature coefficient TCF of the resonance frequency, and the second dielectric used for the acoustic wave element 31 (the second element) is formed of a second dielectric material having a second value for the temperature coefficient TCF of the resonance frequency.

The first dielectric and the second dielectric may be selected so that the absolute value of the sum of the first value and the second value or the absolute value of the average value of the first value and the second value are less than the absolute value of the second value. Even when it is difficult to reduce the absolute value of the temperature coefficient TCF of the resonance frequency of one of the first dielectric and the second dielectric, the other of the first dielectric and the second dielectric is selected so as to satisfy the above-mentioned requirements. With this, it is possible to suppress changes of the characteristics (the resonance frequency) of the sub circuit including the third circuit section 30. As a result, according to the exemplary embodiment, it is possible to suppress changes of the pass attenuation characteristics of the band-pass filter circuit 5 due to temperature variations.

For example, when one of the first value and the second value is a negative value, the other of the first value and the second value is set to a positive value. With this, the absolute value of the sum of the first value and the second value can be set to a value less than the absolute value of the second value. In an example, the first value is 40 ppm/K, and the second value is −25 ppm/K.

When both the first value and the second value are negative values, the absolute value of the first value is set to a value less than the absolute value of the second value. With this, the absolute value of the average value of the first value and the second value can be set to a value less than the absolute value of the second value. In an example, the first value is −5 ppm/K, and the second value is −25 ppm/K.

Both the sum of the first value and the second value and the average value of the first value and the second value may fall within a range from −75 to 40 ppm/K, for example.

### MODIFICATION EXAMPLES

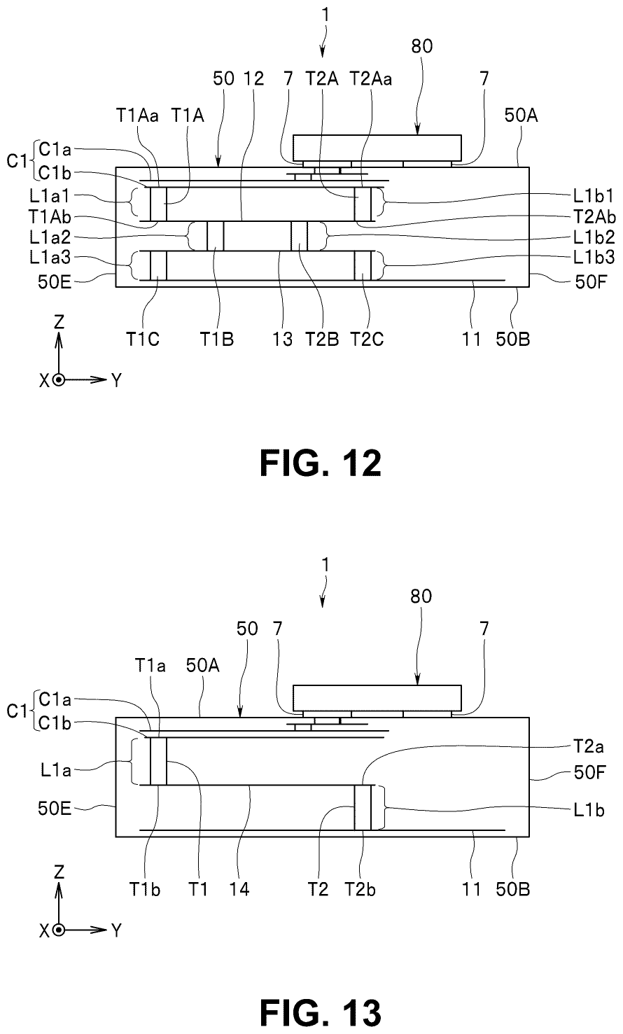

Next, first and second modification examples of the electronic component 1 according to the exemplary embodiment are described. First, with reference to FIG. 12, the first modification example is described. FIG. 12 is a side view showing a part of the internal structure of the first main body 50 in the first modification example. In the first modification example, in place of the first and second inductor portions L1a and L1b, the inductor L1 includes inductor portions L1a1 and L1b1 that are connected to each other in parallel, inductor portions L1a2 and L1b2 that are connected to each other in parallel, and inductor portions L1a3 and L1b3 that are connected to each other in parallel.

In the first modification example, the first main body 50 includes columnar conductors T1A, T1B, T1C, T2A, T2B, and T2C in place of the first and second columnar conductors T1 and T2. The inductor portions L1a1, L1a2, and L1a3 are formed of the columnar conductors T1A, T1B, and T1C, respectively. The inductor portions L1b1, L1b2, and L1b3 are formed of the columnar conductors T2A, T2B, and T2C respectively.

The columnar conductors T1A, T1B, and T1C are arrayed along the Z direction in the stated order. In the example shown in FIG. 12, the columnar conductors T1A and T1C are arranged at the same position in a direction parallel to the Y direction. The columnar conductor T1B is arranged ahead of the columnar conductors T1A and T1C in the Y direction.

The columnar conductor T1A includes a first end T1Aa and a second end T1Ab that are located on sides opposite to each other in a direction parallel to the stacking direction T. The columnar conductor T1B includes a first end and a second end that are located on sides opposite to each other in a direction parallel to the stacking direction T. The columnar conductor T1C includes a first end and a second end that are located on sides opposite to each other in a direction parallel to the stacking direction T.

The columnar conductors T2A, T2B, and T2C are arrayed along the Z direction in the stated order. In the example shown in FIG. 12, the columnar conductors T2A and T2C are arranged at the same position in a direction parallel to the Y direction. The columnar conductor T2B is arranged ahead of the columnar conductors T2A and T2C in the −Y direction.

The columnar conductor T2A includes a first end T2Aa and a second end T2Ab that are located on sides opposite to each other in a direction parallel to the stacking direction T. The columnar conductor T2B includes a first end and a second end that are located on sides opposite to each other in a direction parallel to the stacking direction T. The columnar conductor T2C includes a first end and a second end that are located on sides opposite to each other in a direction parallel to the stacking direction T.

The first end T1Aa of the columnar conductor T1A and the first end T2Aa of the columnar conductor T2A are electrically connected to the capacitor conductor layer C1b forming the capacitor C1.

In the first modification example, the first main body 50 further includes two conductor layers 12 and 13 each extending along an orthogonal direction orthogonal to the stacking direction T. The conductor layers 12 and 13 are arranged between the capacitor conductor layer C1b and the conductor layer 11. The conductor layer 12 is arranged at a position closer to the capacitor conductor layer C1b than the conductor layer 13. The conductor layer 13 is arranged at a position closer to the conductor layer 11 than the conductor layer 12.

The second end T1Ab of the columnar conductor T1A, the second end T2Ab of the columnar conductor T2A, the first end of the columnar conductor T1B, and the first end of the columnar conductor T2B are connected to the conductor layer 12. The second end of the columnar conductor T1B, the second end of the columnar conductor T2B, the first end of the columnar conductor T1C, and the first end of the columnar conductor T2C are connected to the conductor layer 13. The second end of the columnar conductor T1C and the second end of the columnar conductor T2C are connected to the conductor layer 11.

Next, with reference to FIG. 13, the second modification example is described. FIG. 13 is a side view showing a part of the internal structure of the first main body 50 in the second modification example. In the second modification example, the second columnar conductor T2 is arranged ahead of the first columnar conductor T1 in the −Z direction. The first end T1a of the first columnar conductor T1 is electrically connected to the capacitor conductor layer C1b. The second end T2b of the second columnar conductor T2 is electrically connected to the conductor layer 11.

In the second modification example, the first main body 50 includes a conductor layer 14 extending along an orthogonal direction orthogonal to the stacking direction T. In the second modification example, the second end T1b of the first columnar conductor T1 and the first end T2a of the second columnar conductor T2 are electrically connected to the conductor layer 14.

Note that the disclosure is not limited to the exemplary embodiment described above, and various modifications can be made thereto. For example, the electronic component of the disclosure is applicable not only to a band-pass filter but also to other filters such as a low-pass filter and a high-pass filter, and is applicable to an electronic component including a plurality of resonators, such as a branching filter that splits a plurality of signals in different frequency bands.

As described above, an electronic component according to one embodiment of a first aspect of the disclosure includes a first main body including a plurality of dielectric layers being stacked together and a first element, a second main body being mounted to the first main body and including a second element, and a circuit including the first element and the second element. The first main body further includes a first columnar conductor extending in a direction parallel to a stacking direction of the plurality of dielectric layers and being connected to the ground. The first element is a capacitor including a capacitor conductor layer extending along an orthogonal direction orthogonal to the stacking direction. The capacitor conductor layer is arranged between the second element and the first columnar conductor.

In the electronic component according to one embodiment of the first aspect of the disclosure, the first main body may further include a first surface on which the second main body is mounted and a second surface opposite to the first surface. The first columnar conductor may be arranged between the capacitor conductor layer and the second surface.

In the electronic component according to one embodiment of the first aspect of the disclosure, the first columnar conductor may form an inductor. The circuit may further include the inductor.

In the electronic component according to one embodiment of the first aspect of the disclosure, the second element may be connected to the capacitor conductor layer.

In the electronic component according to one embodiment of the first aspect of the disclosure, the first main body may further include a first conductor layer extending along the orthogonal direction and a second columnar conductor extending in a direction parallel to the stacking direction. One end of the first columnar conductor and one end of the second columnar conductor may be connected to the first conductor layer. The first conductor layer and the capacitor conductor layer may face each other. The first main body may further include a second conductor layer extending along the orthogonal direction. The other end of the first columnar conductor and the other end of the second columnar conductor may be connected to the second conductor layer. The first columnar conductor and the second columnar conductor may form a first inductor and a second inductor, respectively. The circuit may further include the first inductor and the second inductor. The first inductor and the second inductor may be connected to each other in parallel.

In the electronic component according to one embodiment of the first aspect of the disclosure, the first main body may further include a first conductor layer extending along the orthogonal direction. A shape of the capacitor conductor layer when seen in the stacking direction may be similar to a shape of the first conductor layer when seen in the stacking direction.

In the electronic component according to one embodiment of the first aspect of the disclosure, the circuit may further include a sub circuit including a first signal port, a second signal port, and a signal path connecting the first signal port and the second signal port to each other. The first element and the second element may be connected to each other in series, and may be provided between the signal path and the ground in the circuit configuration. A resonance frequency of the sub circuit may be higher than a resonance frequency of the sub circuit in a case in which the first element is not provided.

In the electronic component according to one embodiment of the first aspect of the disclosure, the second main body may overlap with a part of the first element when seen in the stacking direction.

In the electronic component according to one embodiment of the first aspect of the disclosure, the second element may be an acoustic wave element.

An electronic component according to one embodiment of a second aspect of the disclosure includes a first main body including a plurality of dielectric layers, a capacitor, and an inductor, a second main body being mounted to the first main body and including an acoustic wave element, and a circuit. The circuit includes a first signal port, a second signal port, and a signal path connecting the first signal port and the second signal port to each other. The acoustic wave element is provided between the signal path and the ground in the circuit configuration. The capacitor and the inductor are connected to each other in series, and are provided between the acoustic wave element and the ground in the circuit configuration.

In the electronic component according to one embodiment of the second aspect of the disclosure, the inductor may include a plurality of inductor portions. In the circuit configuration, the plurality of inductor portions may be connected to each other in parallel.

In the electronic component in the first aspect of the disclosure, the capacitor conductor layer is arranged between the second element and the first columnar conductor. With this, according to the disclosure, the overall characteristics of the electronic component can be achieved as the desired characteristics.

In the electronic component in the second aspect of the disclosure, the capacitor and the inductor are connected to each other in series, and are provided between the acoustic wave element and the ground in the circuit configuration. With this, according to the disclosure, the overall characteristics of the electronic component can be achieved as the desired characteristics.

Based on the above description, obviously, various forms and modifications of the disclosure can be implemented. Thus, within the scope of the appended claims and equivalents thereof, the disclosure can be implemented in forms other than the above example embodiments.

1. An electronic component comprising:
a first main body including a plurality of dielectric layers being stacked together and a first element;
a second main body being mounted to the first main body and including a second element; and
a circuit including the first element and the second element, wherein
the first main body further includes a first columnar conductor extending in a direction parallel to a stacking direction of the plurality of dielectric layers and being connected to a ground,
the first element is a capacitor including a capacitor conductor layer extending along an orthogonal direction orthogonal to the stacking direction, and
the capacitor conductor layer is arranged between the second element and the first columnar conductor.

2. The electronic component according to claim 1, wherein
the first main body further includes a first surface on which the second main body is mounted and a second surface opposite to the first surface, and
the first columnar conductor is arranged between the capacitor conductor layer and the second surface.

3. The electronic component according to claim 1, wherein
the first columnar conductor forms an inductor, and
the circuit further includes the inductor.

4. The electronic component according to claim 1, wherein
the second element is connected to the capacitor conductor layer.

5. The electronic component according to claim 1, wherein
the first main body further includes a first conductor layer extending along the orthogonal direction and a second columnar conductor extending in a direction parallel to the stacking direction, and
one end of the first columnar conductor and one end of the second columnar conductor are connected to the first conductor layer.

6. The electronic component according to claim 5, wherein
the first conductor layer and the capacitor conductor layer face each other.

7. The electronic component according to claim 5, wherein
the first main body further includes a second conductor layer extending along the orthogonal direction, and
the other end of the first columnar conductor and the other end of the second columnar conductor are connected to the second conductor layer.

8. The electronic component according to claim 5, wherein
the first columnar conductor and the second columnar conductor form a first inductor and a second inductor, respectively,
the circuit further includes the first inductor and the second inductor, and
the first inductor and the second inductor are connected to each other in parallel.

9. The electronic component according to claim 1, wherein
the first main body further includes a first conductor layer extending along the orthogonal direction, and
a shape of the capacitor conductor layer when seen in the stacking direction is similar to a shape of the first conductor layer when seen in the stacking direction.

10. The electronic component according to claim 1, wherein
the circuit further includes a sub circuit including a first signal port, a second signal port, and a signal path connecting the first signal port and the second signal port to each other,
the first element and the second element are connected to each other in series, and are provided between the signal path and the ground in a circuit configuration, and
a resonance frequency of the sub circuit is higher than a resonance frequency of the sub circuit in a case in which the first element is not provided.

11. The electronic component according to claim 1, wherein
the second main body overlaps with a part of the first element when seen in the stacking direction.

12. The electronic component according to claim 1, wherein
the second element is an acoustic wave element.

13. An electronic component comprising:
a first main body including a plurality of dielectric layers, a capacitor, and an inductor;
a second main body being mounted to the first main body and including an acoustic wave element; and
a circuit, wherein
the circuit includes a first signal port, a second signal port, and a signal path connecting the first signal port and the second signal port to each other,
the acoustic wave element is provided between the signal path and a ground in a circuit configuration, and
the capacitor and the inductor are connected to each other in series, and are provided between the acoustic wave element and the ground in the circuit configuration.

14. The electronic component according to claim 13, wherein
the inductor includes a plurality of inductor portions, and
the plurality of inductor portions are connected to each other in parallel in the circuit configuration.
